(19) United States
(12) Patent Application Publication
(10) Pub. No.: US 2024/0387714 A1
(43) Pub. Date: Nov. 21, 2024

(54) SEMICONDUCTOR DEVICE

(71) Applicant: SANKEN ELECTRIC CO., LTD., Niiza-Shi, Saitama (JP)

(72) Inventor: Shigenobu MATSUDA, Fujimino-Shi (JP)

(73) Assignee: SANKEN ELECTRIC CO., LTD., Niiza-Shi, Saitama (JP)

(21) Appl. No.: 18/666,872

(22) Filed: May 17, 2024

(30) Foreign Application Priority Data
May 19, 2023 (JP) 2023-083085

(51) Int. Cl. H01L 29/739; H01L 29/423; H01L 29/43

(52) U.S. Cl. CPC H01L 29/7397; H01L 29/42324; H01L 29/435

(57) ABSTRACT

The semiconductor device according to one or more embodiments includes a first semiconductor region of a first conductivity type, a second semiconductor region of the second conductivity type formed on the first semiconductor region, and a semiconductor region containing a first trench structure in which a gate electrode is formed via an insulating film on the second semiconductor region, a third semiconductor region of the second conductivity type provided electrically connected to the second semiconductor region in a planar view, and a gate resistance region including a second trench structure in which a gate resistor is formed via an insulating film on the third semiconductor region. The depth of the third semiconductor region is deeper than the depth of the second semiconductor region and shallower than the trench depth of the second trench structure.

### CROSS REFERENCE TO RELATED APPLICATIONS

This application claims priority to prior Japanese Patent Application No. 2023-083085 filed with the Japan Patent Office on May 19, 2023, the entire contents of which are incorporated herein by reference.

### BACKGROUND

The disclosure relates to semiconductor devices.

In recent years, as a power semiconductor element a switching element having an insulated gate structure such as Insulated Gate Bipolar Transistor (hereinafter referred to as IGBT) and Metal Oxide Semiconductor Field Effect Transistor (hereinafter referred to as MOSFET) is used.

The following are examples of related art.
JP2003-197914 (Patent Document 1)
JP2023-17246 (Patent Document 2)
JP2013-62523 (Patent Document 3)
JP2023-8669 (Patent Document 4)

In order to suppress variations in the characteristics of the semiconductor chip, a semiconductor device in which a resistance region as a gate resistive circuit is built into the semiconductor chip separately from the resistance of the gate electrode and the gate wiring (gate runner) is disclosed. Such a semiconductor device includes, for example, a polysilicon resistor formed via an insulating film on the semiconductor substrate surface between the gate pad and the gate wiring.

For example, when a semiconductor element having a trench gate structure is provided in the active region and a polysilicon resistor is formed via an insulating film on the surface of the semiconductor substrate, a polysilicon resistor on the surface of the semiconductor substrate may be formed in a separate process from the trench gate structure. In this case, by providing a polysilicon resistor, the manufacturing process increase and the area of the semiconductor device increases. Therefore, a trench structure is also used for the polysilicon resistor, but a breakdown may occur in the gate resistance region in which the polysilicon resistor of the trench structure is formed.

### SUMMARY

The semiconductor device according to one or more embodiments may include a first semiconductor region of the first conductivity type, a second semiconductor region of the second conductivity type formed on the first semiconductor region, a semiconductor region having a first trench structure in which a gate electrode is formed via a first insulating film on the second semiconductor region, a third semiconductor region of the second conductivity type provided electrically connected to the second semiconductor region outside the semiconductor region, and a gate resistance region having a second trench structure in which a gate resistor is formed via a second insulating film on the third semiconductor region. The depth of the third semiconductor region may be deeper than the depth of the second semiconductor region, and may be shallower than the trench depth of the second trench structure.

### BRIEF DESCRIPTION OF DRAWINGS

FIG. 1A is a diagram illustrating an upper surface of a part of a semiconductor device according to one or more embodiments.

FIG. 1B is a diagram illustrating an upper surface of an overall structure of a semiconductor device according to one or more embodiments.

FIG. 2 is a diagram illustrating a cross-sectional view along the I-I line of FIG. 1A, as an example.

FIG. 3 is a diagram illustrating a cross-sectional view along the II-II lines of FIG. 1A, as an example.

FIG. 4 is a diagram illustrating a cross-sectional view along the III-III lines of FIG. 1A, as an example.

FIG. 5 is a diagram illustrating a cross-sectional view along the IV-IV lines of FIG. 1A, as an example.

FIG. 6 is a diagram illustrating a cross-sectional view along the V-V line of FIG. 1A, as an example.

FIG. 7 is a diagram illustrating a cross-sectional view along the VI-VI lines of FIG. 1A, as an example.

FIG. 8A is a diagram illustrating an upper surface of a gate resistance trench structure of a semiconductor device according to one or more embodiments.

FIG. 8B is a diagram illustrating a cross-sectional view along the VII-VII lines of FIG. 8A, as an example.

FIG. 9 is a diagram illustrating an upper surface of a part of a semiconductor device according to variation 1.

FIG. 10 is a diagram illustrating an upper surface of an overall structure of a semiconductor device according to variation 1.

FIG. 11A is a diagram illustrating an upper surface of a part of a semiconductor device according to variation 2.

FIG. 11B is a diagram illustrating an upper surface of an overall structure of a semiconductor device according to variation 2.

FIG. 12 is a diagram illustrating an upper surface of an overall structure of a semiconductor device according to variation 3.

FIG. 13 is a diagram illustrating an upper surface of an overall structure of a semiconductor device according to variation 4.

FIG. 14 is a diagram illustrating a cross-section of a semiconductor device according to variation 5.

FIG. 15 is a diagram illustrating a detailed top surface of a gate resistance trench structure of a semiconductor device according to variation 5.

### DETAILED DESCRIPTION

With reference to the drawings, one or more embodiments are described. In the description of the following drawings, the same or similar parts are denoted by the same or similar numerals. However, it should be noted that the drawings are schematic, and the relationship between the thickness and the planar dimensions, the ratio of the length of each part, etc. are different from the real ones. Therefore, the specific dimensions should be judged with reference to the following explanation. In addition, there are parts where the relationship and proportions of the dimensions of each other are different between the drawings.

Further, the embodiments described below are examples of an apparatus or method for embodying a technical idea, and the technical idea, and does not limit the shape, structure, arrangement, or the like of the component parts as follows. One or more embodiments may make various changes within the scope of the technical idea. In the following description, terms specifying the upper and lower surfaces, such as “upper surface” and “lower surface”, are used for the convenience of description, and are included in the technical concept even if they are provided on the sides, for example. In addition, “on” includes not only the case where it is formed in contact with the object, but also the case where it is formed through another layer.

In the following description, the direction of the semiconductor device may be defined on the XYZ axis. For example, in the cross-sectional view, the left and right directions may be in the X axis direction, the vertical direction may be in the Y axis direction, and the direction perpendicular to the XY plane may be in the Z axis direction. These directions are examples. It may be changed accordingly depending on the arrangement of the pattern. In the following description, IGBT is mainly described as a semiconductor device, but it may be a MOSFET. Alternatively, a circuit of other insulated gate structures may be used such as Injection Enhanced Gate Transistor (IEGT) or Reverse Conducting IGBT (RC-IGBT). It may also be a Super Junction MOSFET or a Complementary Metal Oxide Semiconductor Field Effect Transistor (CMOSFET).

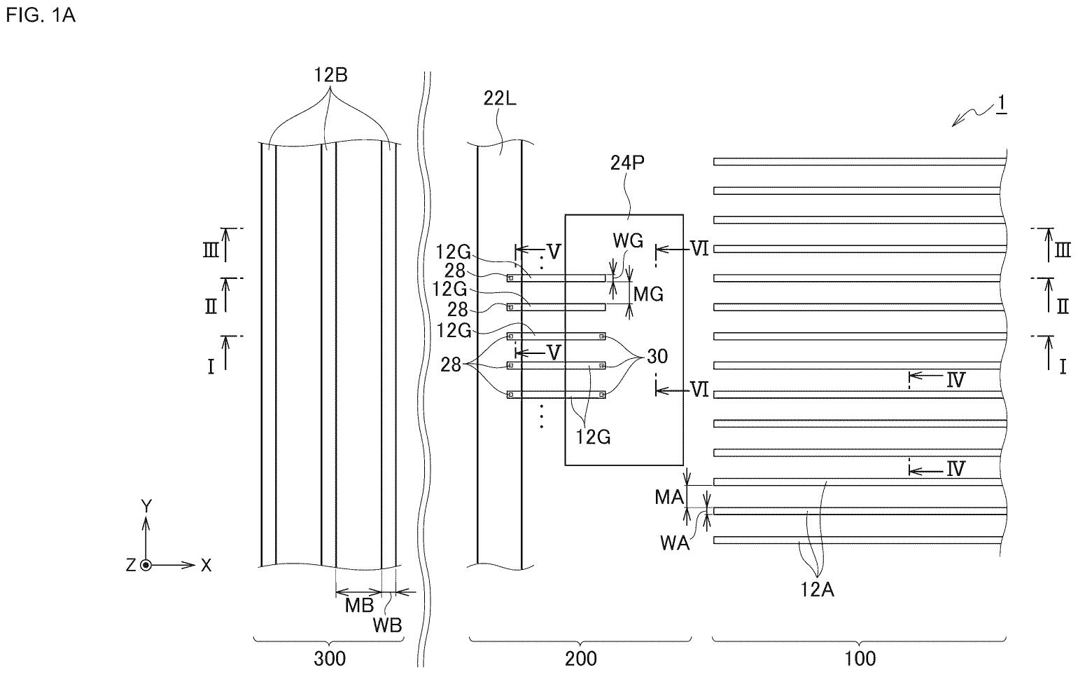

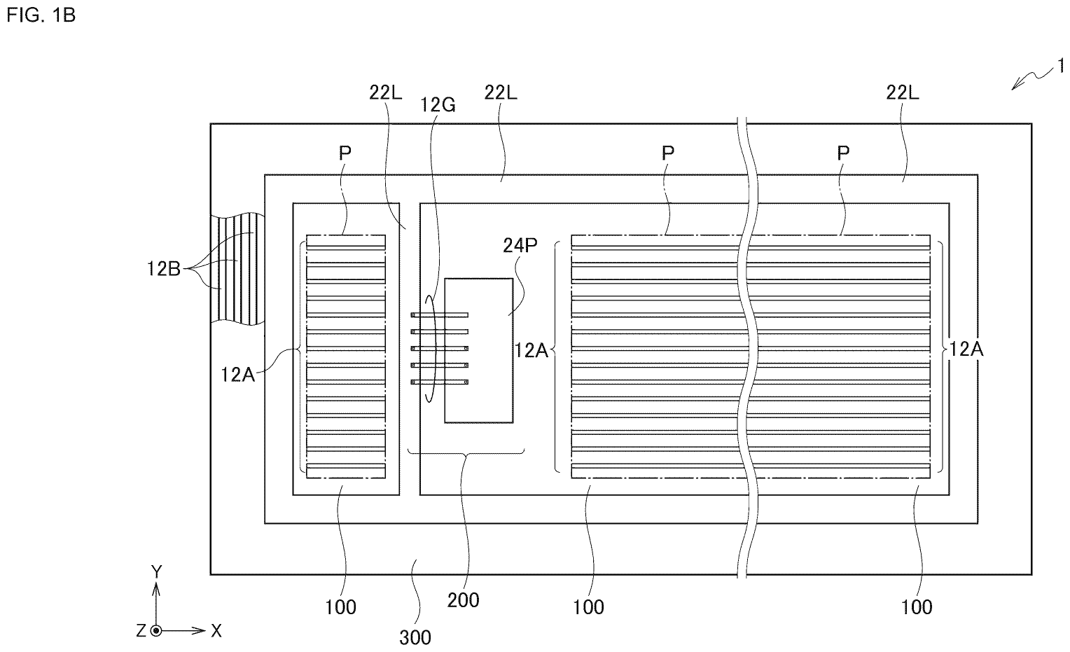

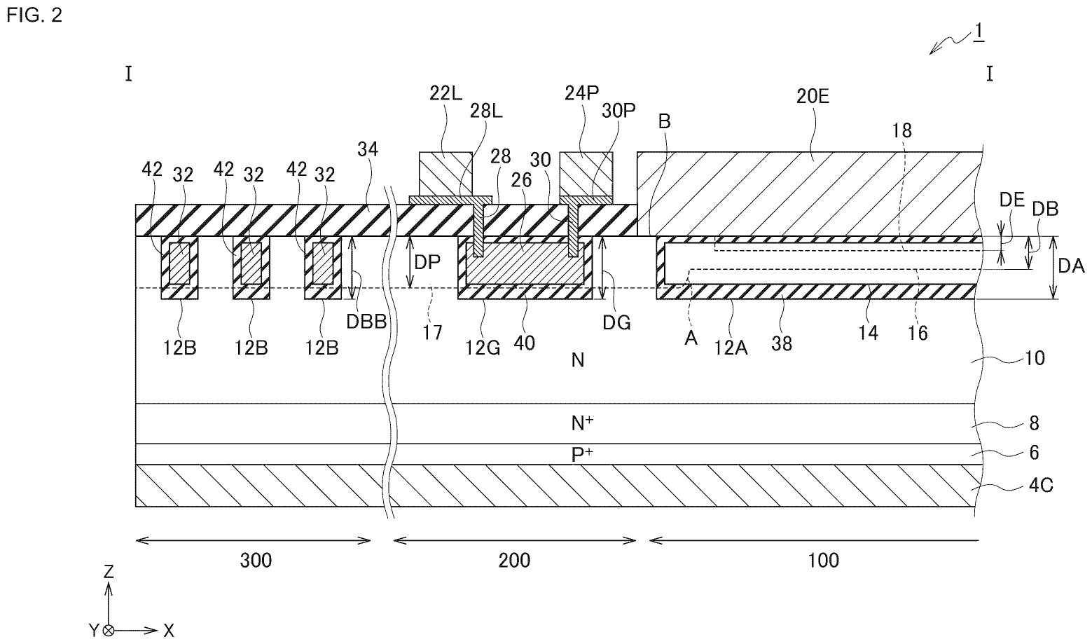

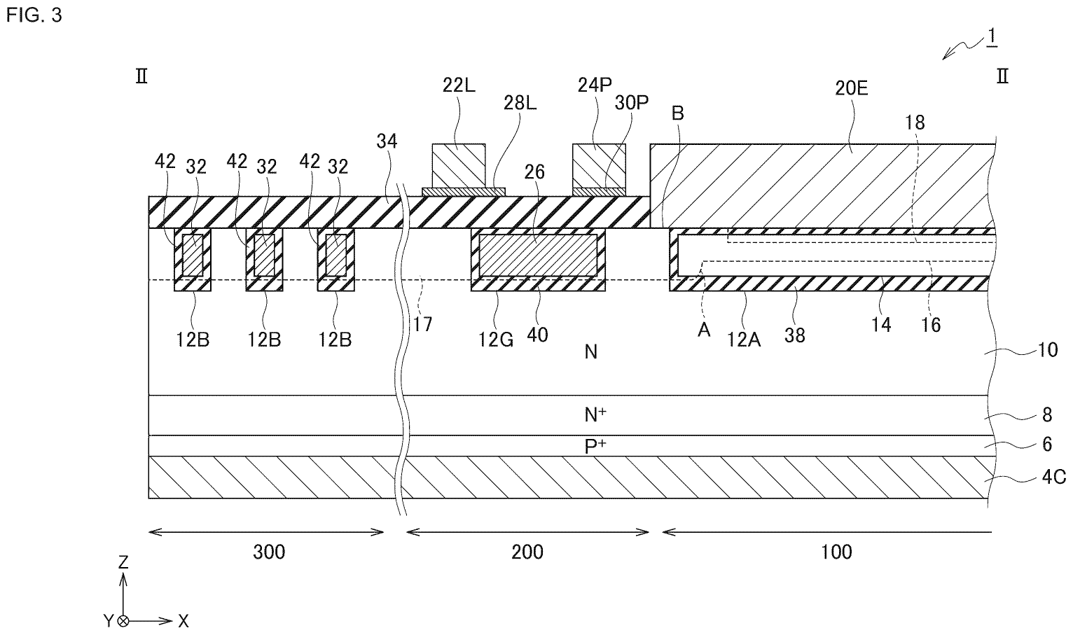

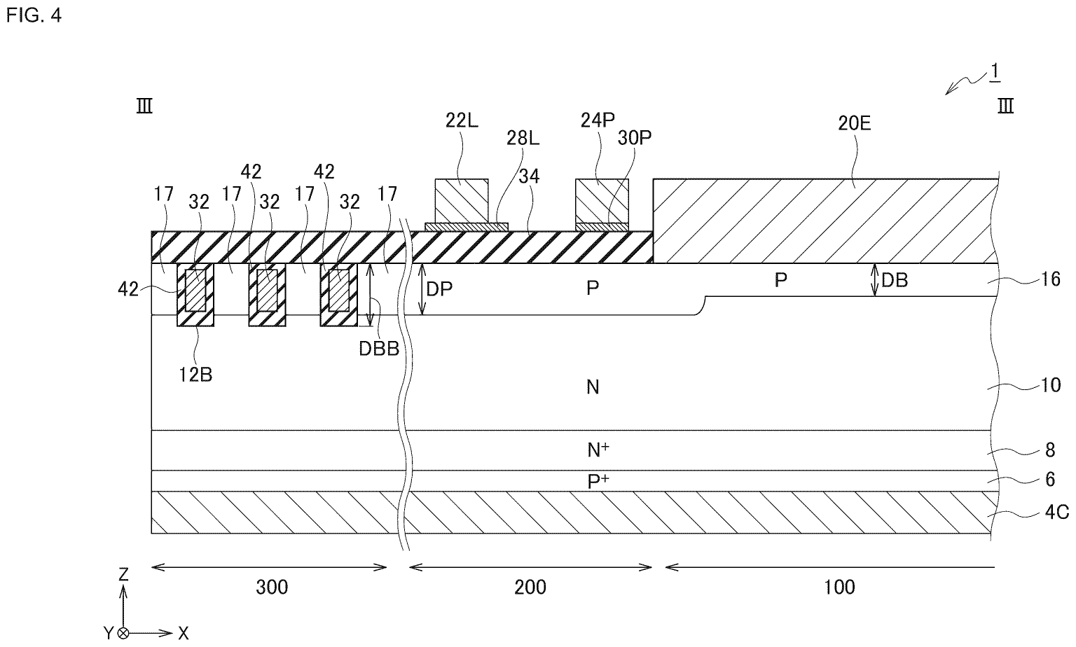

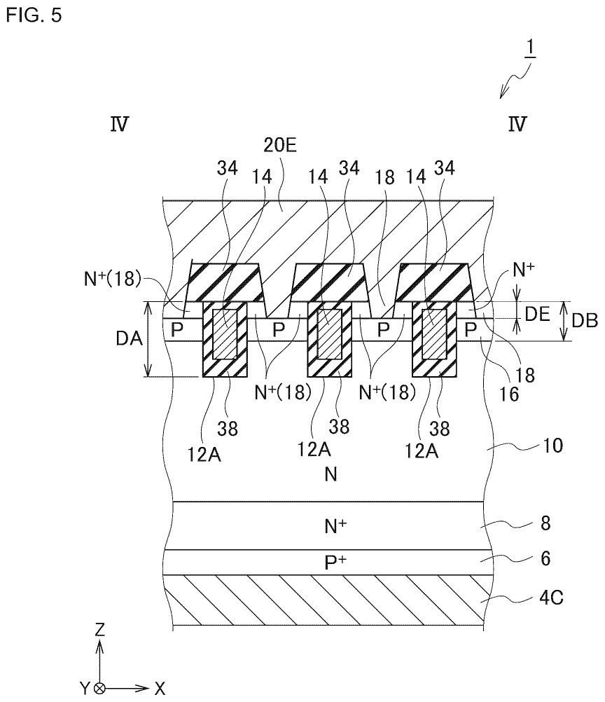

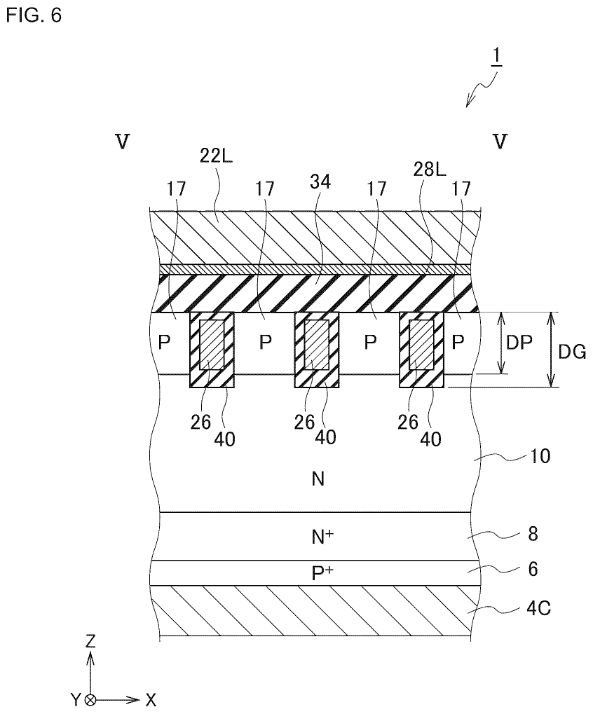

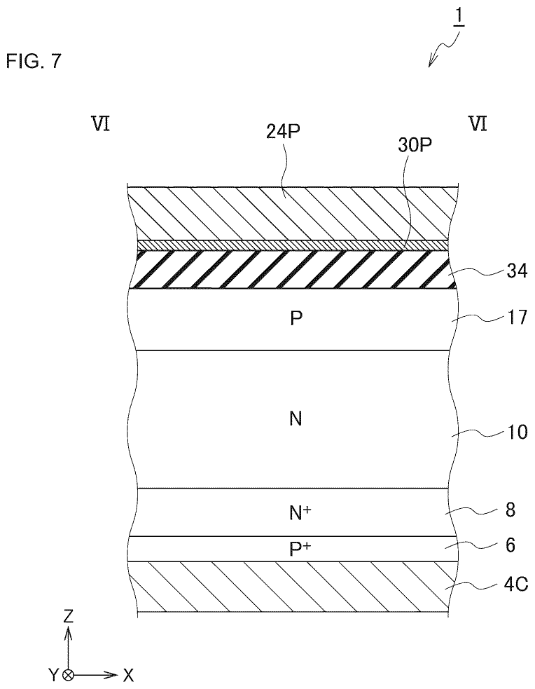

FIG. 1A illustrates a top view of a portion of the semiconductor device 1 according to one or more embodiments. FIG. 1B illustrates a top view of the overall structure of the semiconductor device 1 according to one or more embodiments. FIG. 2 illustrates, as an example, a cross-sectional view along the I-I line of FIG. 1A, FIG. 3 illustrates, as an example, a cross-sectional view along the II-II line of FIG. 1A, and FIG. 4 illustrates, as an example, a cross-sectional view along the III-III line of FIG. 1A. FIG. 5 illustrates, as an example, a cross-sectional view along the IV-IV lines of FIG. 1A, FIG. 6 illustrates, as an example, a cross-sectional view along the V-V line of FIG. 1A, and FIG. 7 illustrates, as an example, a cross-sectional view along the VI-VI lines of FIG. 1A.

As shown in FIGS. 1 to 7, the semiconductor device 1 according to one or more embodiments includes a semiconductor region 100, a gate resistance region 200, and a voltage resistance improvement region 300.

The semiconductor region 100 includes a first semiconductor region 10 of the first conductivity type, a second semiconductor region 16 of the second conductivity formed on the first semiconductor region 10, and a gate trench structure 12A in which a gate electrode 14 is formed via a first insulating film 38 on the second semiconductor region 16. In FIG. 1B, the area surrounded by a dashed line P indicates that the gate trench structure 12A is arranged in parallel in the semiconductor region 100, and the longitudinal direction of the gate trench structure 12A is in the X direction.

The gate resistance region 200 includes a third semiconductor region 17 of the second conductivity type provided and electrically connected to the second semiconductor region 16 outside the semiconductor region 100 in a planar view, and a gate resistance trench structure 12G in which a gate resistor 26 is formed via a second insulating film 40 on a third semiconductor region 17. An insulating film 34 is placed on the surface of the semiconductor substrate, and a gate pad 24P and a gate runner 22L are placed on the insulating film 34. The gate resistor 26 is electrically connected to the gate runner 22L through a contact 28 provided in the insulating film 34, and is electrically connected to the gate pad 24P via a contact 30 provided in the insulating film 34. The contact 28 is electrically connected to the gate runner 22L via a conductive layer 28L. Further, the contact 30 is electrically connected to the gate pad 24P via a conductive layer 30P. A part of the contacts 28 and 30 are embedded inside from the upper surface of the gate resistor 26. In FIG. 1B, the longitudinal direction of the gate resistance trench structure 12G is the same X direction as the longitudinal direction of the gate trench structure 12A. Although not shown, the gate runner 22L and the gate electrode 14 may be electrically connected, for example, on the end side of the gate trench structure 12A (for example, the upper side of 12A in FIG. 1B). Further, in FIG. 1B, the gate runner 22L surrounds the semiconductor region 100, but the gate runner 22L may not completely surround the semiconductor region 100 like a C shape. Further, as shown in FIG. 6, the contact 28 and the gate runner 22L are formed via the insulating film 34 across a plurality of gate resistors 26. Although not shown, the contact 30 and the gate pad 24P may be formed via the insulating film 34 across a plurality of gate resistors 26 in the same way. Further, as shown in FIG. 7, the third semiconductor region 17 is also formed in the region between the longitudinal end of the gate resistance trench structure 12G directly below the gate pad 24P and the longitudinal end of the gate trench structure 12A.

In a planar view, the voltage resistance improvement region 300 is provided at least outside the semiconductor region 100 and the gate resistance region 200, and includes the third semiconductor region 17 of the second conductivity type which is electrically connected to the second semiconductor region 16, and a plurality of voltage resistance improvement trench structures 12B in which a floating electrode 32 is formed via a third insulating film 42 on the third semiconductor region 17. In FIG. 2, the third semiconductor region 17 is provided between the adjacent voltage resistance improvement trench structures 12B, and as shown in FIG. 1B, the voltage resistance improvement trench structure 12B is formed to surround the semiconductor region 100 and/or the gate resistance region 200.

When the semiconductor device 1 according to one or more embodiments is configured as an IGBT, as shown in FIGS. 4 and 5, the first semiconductor region 10 is an N-type drift region, the second semiconductor region 16 is a P-type base layer, and the third semiconductor region 17 may be a P-type semiconductor region. In the negative Z direction of the first semiconductor region 10, an N+ type field stop region 8, a P+ collector region 6, and a collector electrode 4C are placed. An emitter region 18 is placed in contact with the first insulating film 38 on the Z direction of the second semiconductor region 16 of the P-base layer, and an emitter electrode 20E is further connected to the second semiconductor region 16 and the emitter region 18 of the P-base layer. When the semiconductor device 1 according to one or more embodiments is configured as an N-channel MOSFET, the P+ collector region 6 is an N+ drain region, and the collector electrode 4C is a drain electrode. The emitter region 18 is an N+ source region, and the emitter electrode 20E is a source electrode.

Here, as shown in FIG. 2, the depth DP of the third semiconductor region 17 from the upper surface of the semiconductor substrate may be deeper than the depth DB of the second semiconductor region 16 from the upper surface of the semiconductor substrate, and may be shallower than a trench depth DG of the gate resistance trench structure 12G from the upper surface of the semiconductor substrate. The reason for forming the depth DP of the third semiconductor region 17 deeper than the depth DB of the second semiconductor region 16 is that in the voltage resistance improvement region 300 of the semiconductor device 1 according to one or more embodiments, a higher breakdown voltage than that of the semiconductor region 100 is realized, and the semiconductor region 100 may be broken down.

As shown in FIG. 2, the trench depth DA of the gate trench structure 12A and the trench depth DG of the gate resistance trench structure 12G may be formed to equal values. The gate trench structure 12A and the gate resistance trench structure 12G may be formed at the same time in the trench forming process to make the characteristic variation associated with the process more uniform.

As shown in FIG. 1, a trench spacing MA of the gate trench structure 12A and a trench spacing MG of the gate resistance trench structure 12G may be formed to equal values. The trench spacing MA of the gate trench structure 12A and the trench spacing MG of the gate resistance trench structure 12G may be formed to equal values to make the characteristic variation associated with the process variation in manufacturing more uniform.

A trench width WA of the gate trench structure 12A and a trench width WG of the gate resistance trench structure 12G may be formed to equal values. The trench width WA of the gate trench structure 12A and the trench width WG of the gate resistance trench structure 12G may be formed to equal values, thereby making the process variation in the manufacturing process more uniform.

Furthermore, the trench spacing MG of the gate resistance trench structure 12G may be formed wider than the trench spacing MA of the gate trench structure 12A. When it is broken down on the semiconductor region 100 side, it may oscillate during switching of the semiconductor device 1. Therefore, the trench spacing MG of the gate resistance region 200 may be wider than the trench spacing MA of the semiconductor region 100, and it may be broken down near the bottom of the trench of the gate resistance region 200. The trench interval may be precisely the pitch of the semiconductor region (mesa portion) between the trenches. When the trench spacing MG of the gate resistance trench structure 12G is wider than the trench spacing MA of the gate trench structure 12A of the semiconductor region 100, the electric lines of force may easily enter the portion of the p-type semiconductor region 17 of the gate resistance trench structure 12G, breakdown may easily occur near the bottom of the trench of the gate resistance region 200.

Further, as shown in FIGS. 1A and 1B, the voltage resistance improvement region 300 may be provided outside the semiconductor region 1 or the gate resistance region 200 in a planar view. Furthermore, the voltage resistance improvement region 300 may be provided outside the semiconductor region 1 and the gate resistance region 200 in a planar view.

As shown in FIGS. 2 to 4, the voltage resistance improvement region 300 includes the third semiconductor region 17, a voltage resistance improvement trench structure 12B formed to penetrate the third semiconductor region 17, and a floating electrode 32 formed via the third insulating film 42 in the voltage resistance improvement trench structure 12B. A trench spacing MB of the voltage resistance improvement region 300 and a trench width WB of the voltage resistance improvement region may be set according to the breakdown voltage. A trench depth DBB of the voltage resistance improvement trench structure 12B may be formed to a value equal to the trench depth DG of the gate resistance trench structure 12G.

The voltage resistance improvement region 300 is provided on the chip end side than the gate resistance region 200 so as to surround the active region 100, and a plurality of trench-type voltage resistance improvement structures are formed within the voltage resistance improvement region 300. The P-type semiconductor region 17 is also formed on the surface of the mesa portion between the trenches of the voltage resistance improvement structure, and the part of the P-type semiconductor region 17 on the gate resistance region 200 side is connected to the P-type semiconductor region 17 of the gate resistance region 200. The P-type semiconductor region 17 of the voltage resistance improvement region 300 is formed deeper than the P-base region 16 as well as the P-type semiconductor region 17 of the gate resistance region 200, and the P-type semiconductor region 17 is divided from the outer P-type semiconductor region 17 by the voltage resistance improvement trench structure 12B. The voltage resistance improvement region 300 surrounds the semiconductor region 100 and the gate resistance region 200. Further, the P-type semiconductor region 17 on the surface of the mesa portion between the trenches of the voltage resistance improvement trench structure 12B in the voltage resistance improvement region 300 and the P-type semiconductor region 17 in the gate resistance region 200 are not divided by the N-type drift region.

Further, as shown in FIGS. 1A and 1B, the gate runner 22L may be provided outside the semiconductor region 100 or the gate resistance region 200 in a planar view. Further, the gate runner 22L may be provided outside the semiconductor region 100 and the gate resistance region 200 in a planar view. The gate runner 22L is provided outside or inside the gate resistance region 200 outside the semiconductor region 100 and inside the voltage resistance improvement region 300. The gate runner 22L is electrically connected to the gate electrode 14 of the semiconductor region 100. Further, the gate runner 22L is connected to a part of the gate resistor 26 via the contact 28 as shown in FIGS. 1A and 2. The gate resistor 26 may be formed by polysilicon.

Therefore, the gate resistance trench structure 12G in the gate resistance region 200 and the gate trench structure 12A in the semiconductor region 100 may be formed at the same time, and the gate resistor 26 may be formed simultaneously with the semiconductor region 100. Further, by using the gate resistance trench structure 12G, the area of the gate resistance may be reduced.

Further, the resistance value may be adjusted depending on the presence or absence of the contact 28 connected to the gate runner 22L and the contact 30 connected to the gate pad 24P. It may be also possible to adjust the breakdown voltage in the gate resistance region by adjusting the trench width WG of the gate resistance trench structure 12G, the trench spacing MG of the gate resistance trench structure 12G, and the length of the gate resistor 26.

Further, as shown in FIGS. 1A and 1B, the gate pad 24P may be provided between the semiconductor region 100 and the gate runner 22L. The gate pad 24P is connected to at least a portion of the gate resistor 26 via the contact 30, as shown in FIGS. 1A and 2. Although not shown in the drawings, external wiring is connected to the gate pad 24P.

### (Gate Resistance Trench Structure)

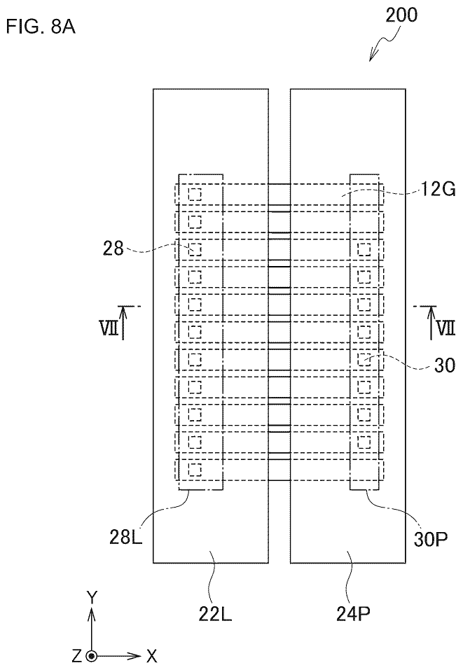

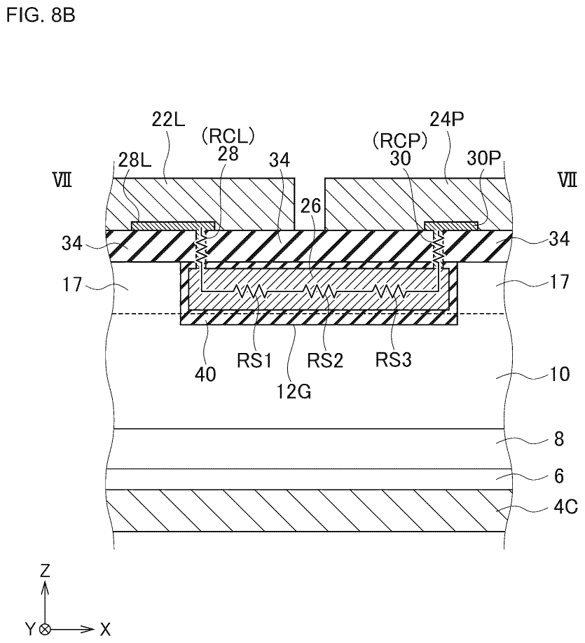

FIG. 8A is a detailed top view of the gate resistance trench structure 12G of the gate resistance region 200, and FIG. 8B is a cross-sectional view along the VII-VII lines of FIG. 8A. In FIGS. 1A and 1B, five gate resistance trench structures 12G are shown, but in FIG. 8A, an example in which 11 gate resistance trench structures 12G are arranged is shown.

The gate resistance region 200 includes a third semiconductor region 17 of the second conductivity type, and a gate resistance trench structure 12G in which a gate resistor 26 is formed via the second insulating film 40 on the third semiconductor region 17. The gate resistor 26 is electrically connected to the gate runner 22L via the contact 28 and to the gate pad 24P via the contact 30. The contact 28 is electrically connected to the gate runner 22L via the conductive layer 28L. Further, the contact 30 is electrically connected to the gate pad 24P via the conductive layer 30P. The gate resistance trench structure 12G is arranged in a plurality as shown in FIG. 8A. As shown in FIG. 8B, a contact resistor RCL is placed between the gate runner 22L and the gate resistor 26, and a contact resistor RCP is placed between the gate pad 24P and the gate resistor 26. Furthermore, resistors RS1, RS2, and RS3 distributed in series are formed inside the gate resistor 26 formed by polysilicon. In the gate resistance trench structure 12G in which the contacts 28 and 30 are formed together, the gate resistor 26 having a predetermined value may be obtained. The gate resistance trench structure 12G in which the contact 30 is not formed does not function as the gate resistor 26. For example, in the first and second gate resistance trench structures 12G from the upper side (Y direction side) of FIG. 8A, the contact 28 is provided and the gate runner 22L and the gate resistor 26 are electrically connected, but the contact 30 is not provided and the gate pad 24P and the gate resistor 26 are not electrically connected. The same applies to the eleventh gate resistance trench structure 12G from the upper side (Y direction side) of FIG. 8A. Therefore, out of the 11 gate resistance trench structures 12G, 8 gate resistors 26 are connected in parallel to function as gate resistors between the gate runner 22L and the gate pad 24P, and the three gate resistance trench structures 12G are unused gate resistors. Thereby, while the gate potential is applied to the potential of the gate resistor 26, the number of gate resistors 26 functioning as gate resistors between the gate pad 24P and the gate runner 22L may be adjusted depending on the presence or absence of contact, and the value of the gate resistance may be adjusted. Depending on the number of gate resistors 26 connected and whether the contacts 28 and 30 are provided, the gate resistance value of the gate resistance region 200 may be appropriately changed even after the gate resistance trench structure 12G is formed. The arrangement of the gate resistance trench structure 12G is not limited to FIG. 8. Further, in one or more embodiments, the value of the gate resistance was adjusted with or without the contact 30, but the contact 30 may be provided in all gate resistance trench structures 12G, and the gate pad 24P and the gate resistor 26 may be electrically connected, and the number of gate resistance trench structures 12G connected in parallel between the gate pad 24P and the gate runner 22L may be adjusted depending on the presence or absence of the contact 28.

In the semiconductor device 1 according to one or more embodiments, the P-type semiconductor region 17 is placed in the semiconductor region sandwiched between the gate resistance trench structure 12G. The semiconductor region 100 side of the P-type semiconductor region 17 is electrically connected to the emitter electrode 20E as shown in region B of FIG. 2. Further, the P-type semiconductor region 17 is connected to the P-base region 16 of the semiconductor region 100. The depth DP of the P-type semiconductor region 17 is deeper than the depth DB of the P-base region 16 and shallower than the trench depth DG of the gate resistance trench structure 12G. The impurity concentration of the P-type semiconductor region 17 is lower than the impurity concentration of the P-base region 16. As a result, compared to the gate resistance trench structure 12G having the P-type semiconductor region 17 and the voltage resistance improvement trench structure 12B, electric field concentration occurs in the vicinity of the gate trench structure 12A of the semiconductor region 100 (near the corner of the bottom of the groove). Further, since the depth DP of the P-type semiconductor region 17 is shallower than the trench depth DG of the gate resistance trench structure 12G, the longer overall process step of the semiconductor device 1 may be avoided.

The direction of trench extension (X direction in FIG. 1A), the width of the trench (WG, WA), the depth of the trench (DG, DA), and the trench spacing (MG, MA) to adjacent trenches may each be equal in the gate trench structure 12A of the semiconductor region (active region) 100 and the gate resistance trench structure 12G. The gate trench structure 12A and the gate resistance trench structure 12G are formed at the same time, and the same trench structure is formed in a wider range in the plane, so that the shape of the trench end may be relatively stable. Thereby, it may be possible not only to share a common process but also to suppress the change in the breakdown position that occurs at the trench end due to manufacturing variations.

As shown in FIG. 5, the P-base region 16 of the semiconductor region (active region) 100 is electrically connected to the emitter electrode 20E. Since the P-base region 16 and the P-type semiconductor region 17 are connected, the P-type semiconductor region 17 and the emitter electrode 20E are electrically connected. Further, in the P-type semiconductor region 17, any part of the end side of the gate trench structure 12A may be directly connected to the emitter electrode 20E. For example, in FIG. 2, the emitter electrode 20E and the P-type semiconductor region 17 are connected in the vicinity of the end B of the active region 100. Therefore, the emitter electrode 20E, the P-base region 16, and the P-type semiconductor region 17 are electrically commonly connected. The emitter electrode 20E is insulated from the gate electrode 14 by the insulating film 34.

As shown at the end A of FIG. 2, the depth DP of the P-type semiconductor region 17 is deeper than the depth DB of the P-base region 16 and shallower than the trench depth DG of the gate resistance trench structure 12G. The starting position (end A) of the P-type semiconductor region 17 in FIG. 2 is on the semiconductor region 100 side (positive X direction) rather than the longitudinal end of the gate trench structure 12A, a P-type semiconductor region 17 is formed in a mesa portion sandwiched between adjacent gate trench structures 12A in the vicinity of the longitudinal end of the gate trench structure 12A.

Since the active region 100 is wider than the gate resistance region 200 and the voltage resistance improvement region 300, the breakdown by concentrating the electric field in the active region 100 may prevent destruction such as burning due to the breakdown current flowing in a narrow region.

### (Variation 1)

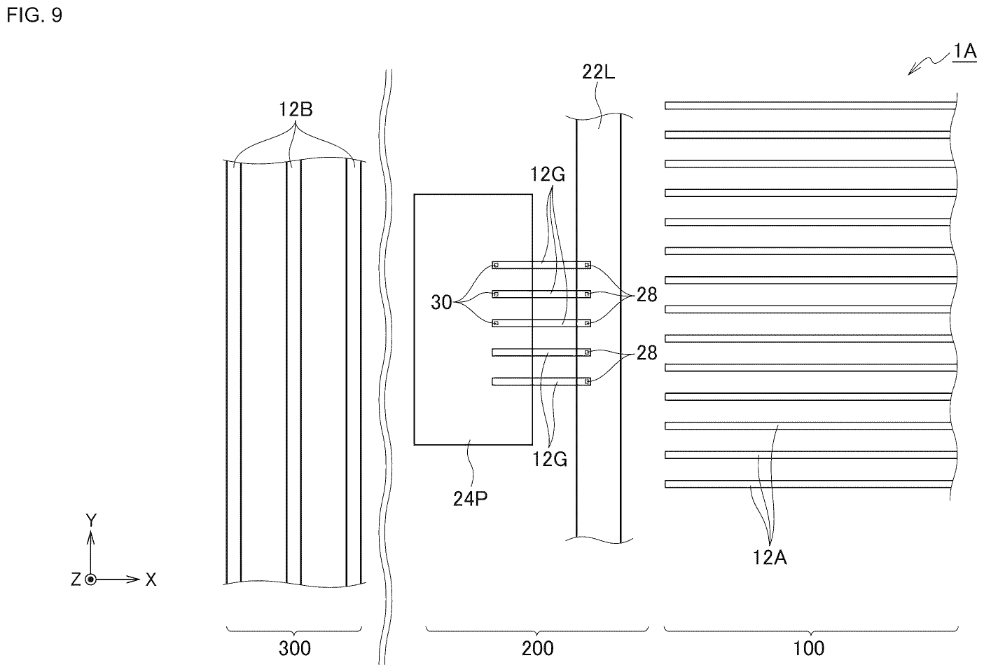

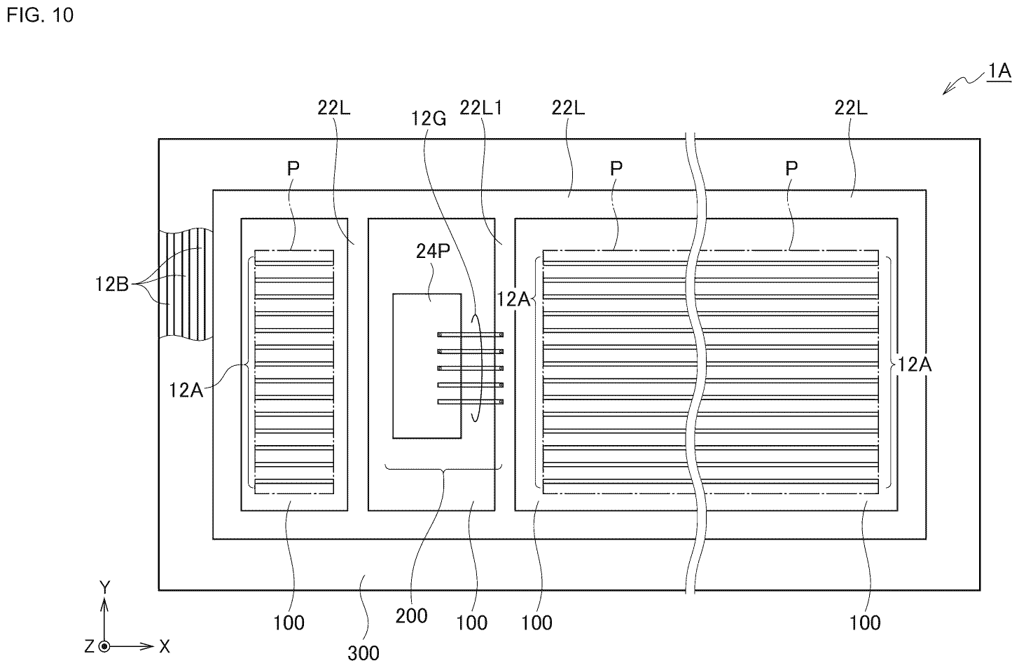

FIG. 9 is a top view of a part of the semiconductor device 1A according to variation 1. FIG. 10 is a top view of the overall structure of the semiconductor device 1A according to variation 1. In FIG. 10, the area surrounded by a dashed line P indicates that the area is for the gate trench structure 12A to be placed in the semiconductor region 100. As shown in FIGS. 9 and 10, the semiconductor device 1A according to variation 1 has a configuration in which the gate runner 22L1 is arranged between the gate resistance region 200 and the semiconductor region 100. Compared to the semiconductor device 1 (FIGS. 1A and 1B) according to one or more embodiments, the gate pad 24P and the gate runner 22L are arranged in opposite directions in the X direction. By arranging in this way, both ends of the gate electrode 14 of the gate trench structure 12A may be easily connected to the gate runner 22L while the longitudinal direction of the gate trench structure 12A is the same X direction as the longitudinal direction of the gate resistance trench structure 12G. As shown in FIG. 10, the gate resistance region 200 may be surrounded by the gate runner 22L. Further, another semiconductor region 100 may be placed outside the gate resistance region 200.

### (Variation 2)

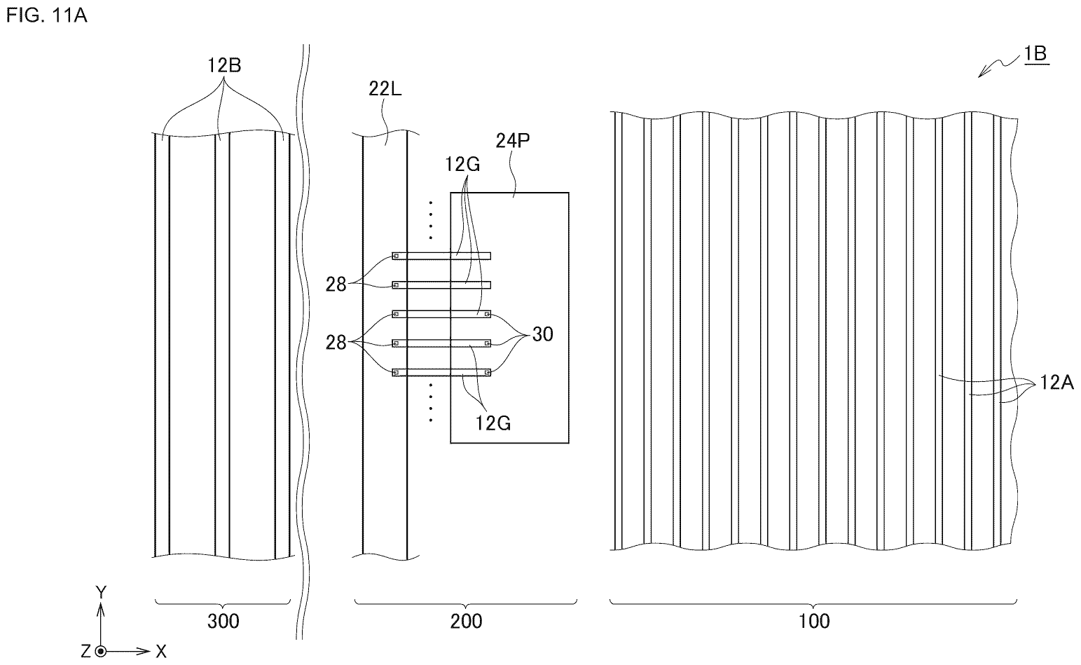

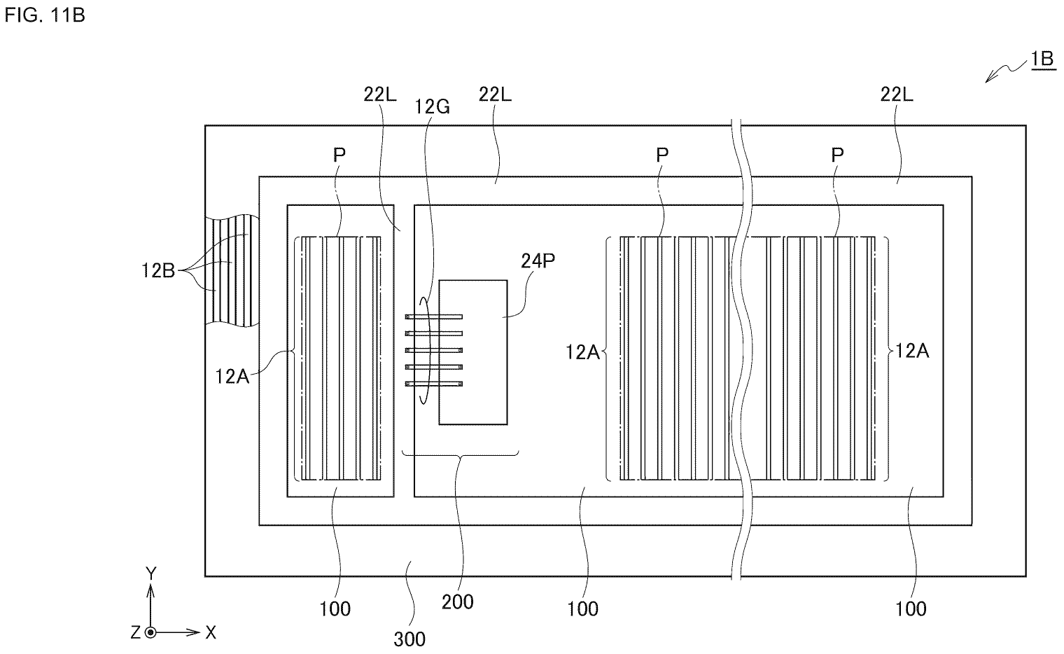

FIG. 11A is a top view of the semiconductor device 1B according to variation 2. FIG. 11B is a top view of the overall structure of the semiconductor device 1B according to variation 2. In FIG. 11B, the area surrounded by the dashed line P indicates that the area is for the gate trench structure 12A to be placed in the semiconductor region 100.

In the semiconductor device 1 according to one or more embodiments and the semiconductor device 1A according to Variation 1, the extension direction (longitudinal direction) of the gate trench structure 12A and the extension direction (longitudinal direction) of the gate resistance trench structure 12G are both X directions. That is, the extending direction of the gate trench structure 12A and the extending direction of the gate resistance trench structure 12G are the same direction as each other. On the other hand, as shown in FIGS. 11A and 11B, in the semiconductor device 1B according to Variation 2, the extension direction of the gate trench structure 12A is the Y direction, and the extension direction of the gate resistance trench structure 12G is the X direction. The extending direction of the gate trench structure 12A and the extending direction of the gate resistance trench structure 12G may be nonparallel to each other. By arranging the extension direction of the gate trench structure 12A in the Y direction, the length of the gate runner 22L from the contact 28 to the connection point with the gate electrode 14 of the gate trench structure 12A may be secured to a certain length or more. Further, by arranging the extension direction of the gate trench structure 12A in the Y direction, it may be possible to improve the response variation of the electrical signal from the gate runner 22L placed in the positive or negative Y direction to the gate electrode 14 of the gate trench structure 12A.

### (Variation 3)

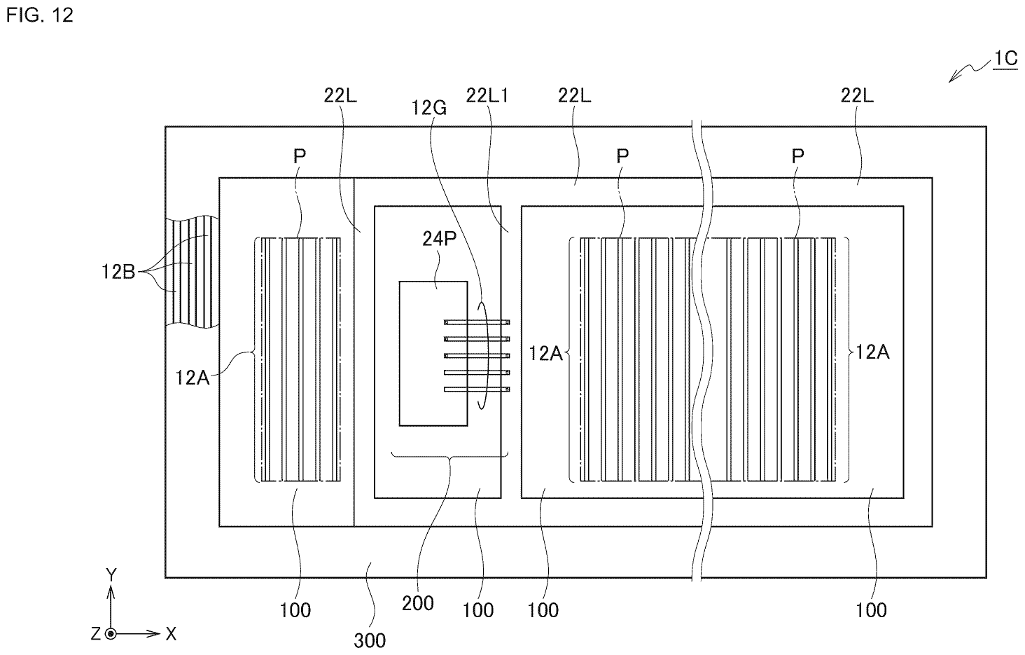

FIG. 12 is a top view of the overall structure of the semiconductor device 1C according to variation 3. In FIG. 12, the area surrounded by a dashed line P indicates that the area is for the gate trench structure 12A to be placed in the semiconductor region 100. In the semiconductor device 1C according to the variation 3, as shown in FIG. 12, the gate runner 22L1 is placed between the gate resistance region 200 and the semiconductor region 100. The gate resistance region 200 may be surrounded by the gate runner 22L. Compared to the semiconductor device 1 (FIGS. 11A and 11B) according to Variation 2, the gate pad 24P and the gate runner 22L are arranged in opposite directions in the X direction. Thus, by arranging the gate resistance region 200, the gate resistor 26 and the gate runner 22L1 are connected, and the gate electrode 14 and the gate runner 22L are connected. Thereby, the length of the gate runner from the connection point between the gate resistor 26 and the gate runner 22L1 to the connection point between the gate electrode 14 and the gate runner 22L may be secured to a certain length or more. Further, the in-plane variation of the electrical signal to the gate electrode 14 may be improved. Further, another semiconductor region 100 may be placed outside the gate resistance region 200 (in the negative X direction from the gate resistance region 200 in FIG. 12).

### (Variation 4)

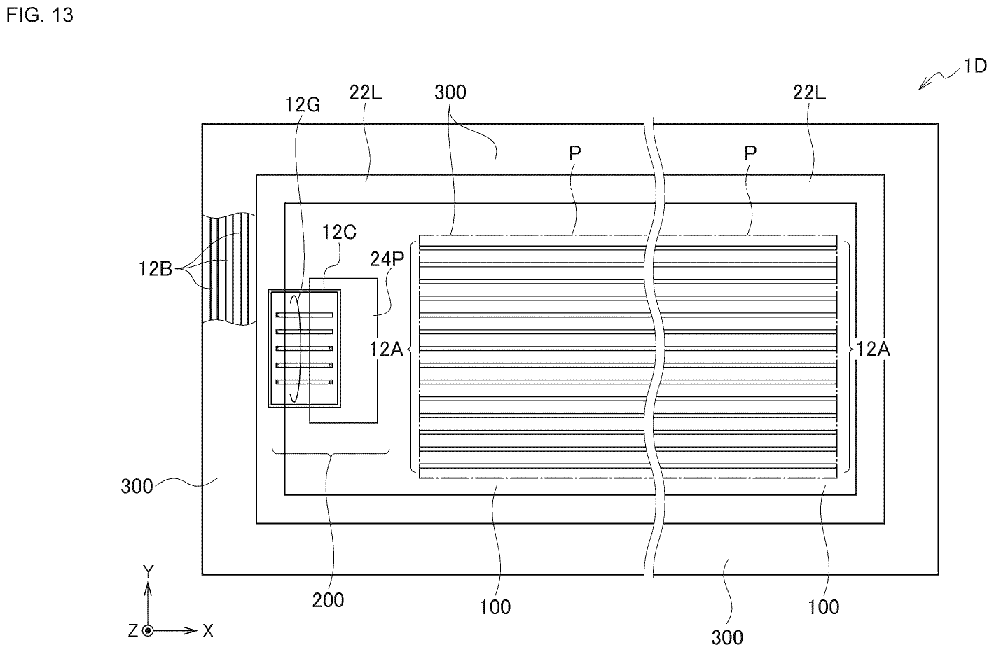

FIG. 13 is a top view of the overall structure of the semiconductor device 1D according to variation 4. In FIG. 13, the area surrounded by a dashed line P indicates that the area is for the gate trench structure 12A to be placed in the semiconductor region 100. The gate resistance region 200 may be surrounded by a trench structure 12C that penetrates the third semiconductor region 17 around the gate resistance region 200. The trench structure 12C may separate the third semiconductor region 17 placed inside surrounded by the trench structure 12C from the base region, and the potential of the third semiconductor region 17 may be set to a floating potential. The periphery of the gate resistance trench structure 12G may be surrounded in an annular shape by at least one trench structure 12C. Further, the voltage resistance improvement trench structure 12B may surround the trench structure 12C and the active region. By surrounding the gate resistance region 200 with the voltage resistance improvement trench structure 12B, it may be possible to suppress the variation in the breakdown voltage at the end portion of the plurality of gate resistance trench structures 12G.

### (Variation 5)

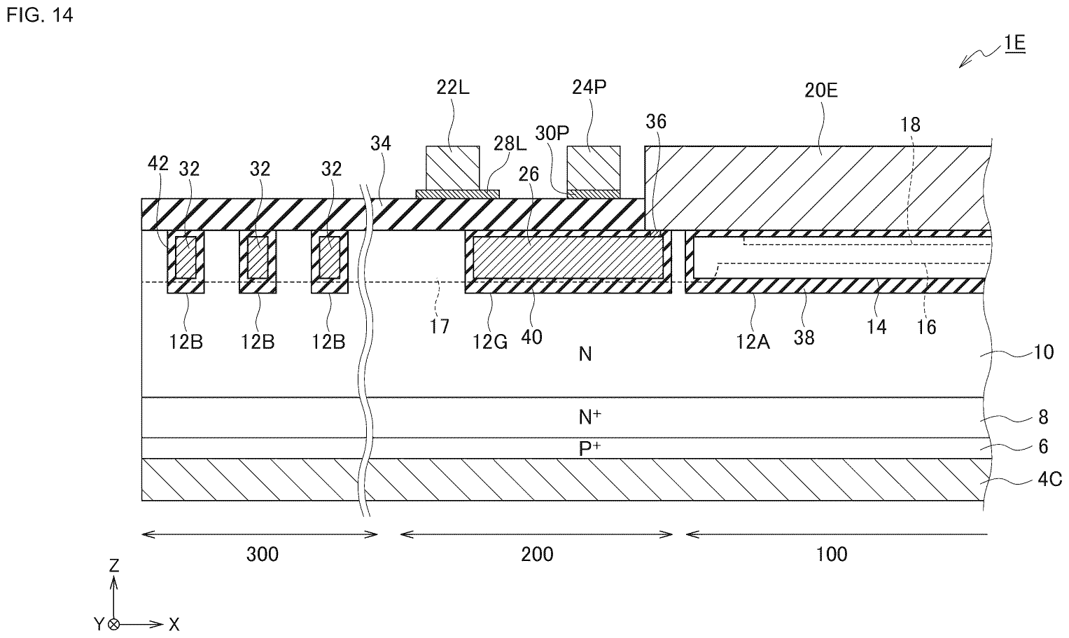

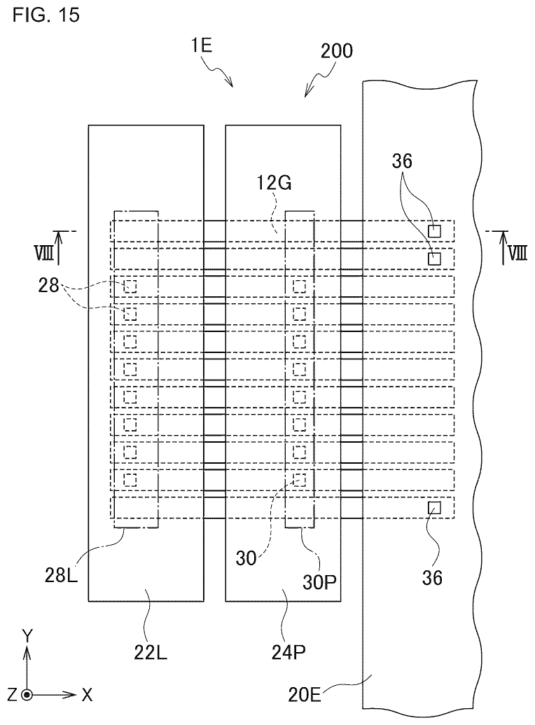

FIG. 14 is a cross-sectional view of the semiconductor device 1E according to variation 5, and FIG. 15 is a plan view of variation 5. In FIG. 14, in the cross-sectional view corresponding to FIG. 3, the emitter electrode 20E is extended in the negative X direction and connected to the gate resistor 26 via an emitter contact 36. FIG. 15 is an enlarged top view of the gate resistance region 200 portion of the semiconductor device 1E according to Variation 5. In FIG. 15, the cross-sectional structure along the VIII-VIII lines corresponds to the vicinity of the gate resistance region 200 of FIG. 14.

When the unused gate resistance trench is a floating potential, the potential of the gate resistor 26 in the unused gate resistance trench may become unstable during the operation of the semiconductor device. Therefore, it may be conceivable to provide only one of the contact 28 connected to the gate runner 22L or the contact 30 connected to the gate pad 24P to provide a gate potential to the gate resistor 26. When a polysilicon gate resistor that does not constitute a gate current path is potentially at the gate potential, an increase in gate capacitance occurs due to a polysilicon gate resistor that does not constitute a gate current path. After forming the gate resistance trench structure 12G and the polysilicon gate resistor 26 provided therein, the gate resistance value is measured, and it is determined whether or not to provide contact (28, 30) with the gate runner 22L and the gate pad 24P. That is, after measuring the resistance value of the gate resistor 26, the process may be greatly increased by additionally forming the gate resistance trench structure 12G and the polysilicon gate resistor 26 provided therein.

As shown in FIGS. 14 and 15, in the semiconductor device 1E according to variation 5, the gate resistance trench structure 12G and the polysilicon gate resistor 26 therein are placed in the positive X direction in the lower side of the region between the gate runner 22L and the gate pad 24P (negative Z direction side). Further, the gate resistance trench structure 12G and the polysilicon gate resistor 26 therein are extended and placed directly below the emitter electrode 20E. The polysilicon gate resistor used as the gate resistor 26 is connected by one via the contact 28 connected to the gate runner 22L, and the other is connected via the contact 30 connected to the gate pad 24P. The polysilicon gate resistor used as the gate resistor 26 does not provide contacts (28 and 30) connected to the gate runner 22L and the gate pad 24P, but is provided with the emitter contact 36 connected to the emitter electrode 20E. As a result, since the polysilicon gate resistor not used as the gate resistor 26 has the same potential as the emitter electrode 20E, it may be possible to suppress an increase in the gate capacitance due to a polysilicon gate resistor not used as the gate resistor 26.

### OTHER EMBODIMENTS

Although one or more embodiments has been described as above, the statements and drawings that form part of the disclosure should not be understood to limit the technical scope. From the disclosure, various alternative embodiments, examples, and operational techniques may become apparent to those skilled in the art. Thus, the technical scope may include various embodiments not described herein.

As described above, the semiconductor device according to one or more embodiments may be able to reduce the breakdown in the gate resistance region.

1. A semiconductor device, comprising:
a first semiconductor region of a first conductivity type;
a second semiconductor region of a second conductivity type formed on the first semiconductor region;
a semiconductor region having a first trench structure in which a gate electrode is formed via a first insulating film on the second semiconductor region;
a third semiconductor region of the second conductivity type arranged so as to be electrically connected to the second semiconductor region outside the semiconductor region; and
a gate resistance region having a second trench structure in which a gate resistor is formed via a second insulating film on the third semiconductor region, wherein
a depth of the third semiconductor region is deeper than a depth of the second semiconductor region, and
the depth of the third semiconductor region is shallower than a trench depth of the second trench structure.

2. The semiconductor device according to claim 1, wherein
a trench depth of the first trench structure and the trench depth of the second trench structure are substantially equal.

3. The semiconductor device according to claim 1, wherein
a trench spacing of the first trench structure and a trench spacing of the second trench structure are substantially equal.

4. The semiconductor device according to claim 1, wherein
a trench width of the first trench structure and a trench width of the second trench structure are substantially equal.

5. The semiconductor device according to claim 1, wherein
a trench spacing of the second trench structure is wider than a trench spacing of the first trench structure.

6. The semiconductor device according to claim 1, further comprising:
in a planar point of view, a voltage resistance improvement region arranged outside the semiconductor region, the voltage resistance improvement region comprises:
the third semiconductor region;
a third trench structure formed to penetrate the third semiconductor region;
a third insulating film placed in the third trench structure; and
a first floating electrode formed via the third insulating film.

7. The semiconductor device according to claim 1, further comprising:
a fourth trench structure placed around the gate resistance region and penetrating the third semiconductor region around the second trench structure, wherein
the fourth trench structure comprises a second floating electrode through an insulating film inside a trench.

8. The semiconductor device according to claim 1, further comprising:
a plurality of second trench structures arranged on the semiconductor region, wherein
at least one second trench structure of the plurality of second trench structures is electrically connected to a gate runner via a first contact, and electrically connected to a gate pad at a distance from the first contact via a second contact; and
at least one second trench structure of the plurality of second trench structures is electrically connected to only one of the gate runner or the gate pad via a third contact.

9. The semiconductor device according to claim 1, further comprising:
a fourth semiconductor region of the first conductivity type placed in contact with the first insulating film on the second semiconductor region; and
a first electrode connected to the second semiconductor region and the fourth semiconductor region, wherein
the first electrode is electrically connected to the third semiconductor region.

10. The semiconductor device according to claim 1, further comprising
in a planar view, a gate pad electrically connected to the gate resistance region between the semiconductor region and the gate resistance region.

11. The semiconductor device according to claim 1, wherein
an extending direction of the first trench structure and an extending direction of the second trench structure are substantially parallel.

12. The semiconductor device according to claim 8, wherein
a plurality of the first trench structures and the plurality of the second trench structures are arranged on the semiconductor region,
an extending direction of the first trench structures and an extending direction of the second trench structures are nonparallel to each other, and
a direction of a portion of the gate runner to which a plurality of gate resistors are connected via contacts and a direction of the portion of the gate runner connected to a plurality of gate electrodes are different.

13. The semiconductor device according to claim 1, further comprising:
a fourth semiconductor region of the first conductivity type arranged in contact with the first insulating film on the second semiconductor region; and
a first electrode connected to the second semiconductor region and the fourth semiconductor region, wherein
the semiconductor device comprises a plurality of second trench structures, and at least one of the second trench structures comprises:
a first contact electrically connected with a gate runner;
a second contact that is separated from the first contact and electrically connected to a gate pad; and
at least one of the second trench structures comprises a fourth contact that is electrically connected to the first electrode.

14. The semiconductor device according to claim 8, further comprising:
a fourth semiconductor region of the first conductivity type placed in contact with the first insulating film on the second semiconductor region; and
a first electrode connected to the second semiconductor region and the fourth semiconductor region, wherein
at least one of the second trench structures comprises a fourth contact that is electrically connected to the first electrode.

15. A semiconductor device, comprising:
a first semiconductor region of a first conductivity type;
a second semiconductor region of a second conductivity type formed on the first semiconductor region;
a semiconductor region comprising a first trench structure in which a gate electrode is formed via a first insulating film on the second semiconductor region;
a third semiconductor region of the second conductivity type provided and electrically connected to the second semiconductor region outside the semiconductor region in a planar view; and
a gate resistance region comprising a plurality of second trench structures comprising polysilicon that is insulated from the third semiconductor region, wherein
a depth of the third semiconductor region is deeper than a depth of the second semiconductor region, and
the depth of the third semiconductor region is shallower than a trench depth of the second trench structures.

16. The semiconductor device according to claim 15, wherein
at least one of the second trench structures comprises:
a first contact that is electrically connected to a gate runner;
a second contact that is separated from the first contact and electrically connected to a gate pad; and
at least one of the second trench structures comprises:
a third contact that electrically connects only to either one of the gate runner or the gate pad.

17. The semiconductor device according to claim 15, wherein
the plurality of the second trench structures comprises:
a first polysilicon that is electrically connected to a gate runner via a first contact and is electrically connected to a gate pad via a second contact; and
a second polysilicon that is electrically connected to the gate runner via a first contact and is not electrically connected to the gate pad via a second contact.

18. The semiconductor device according to claim 15, wherein
the polysilicon comprises:
a first polysilicon that is electrically connected to a gate runner via a first contact and electrically connected to a gate pad via a second contact; and
a second polysilicon that is not electrically connected to the gate runner via a first contact and is electrically connected to the gate pad via a second contact.

19. The semiconductor device according to claim 15, wherein
each of at least two of the second trench structures comprise:
a first contact that is electrically connected to a gate runner; and
a second contact that is separated from the first contact and electrically connected to a gate pad, and
the polysilicon comprises:
a first polysilicon comprising at least a second trench structure of the plurality of second trench structures, the first polysilicon is electrically connected to the gate runner via a first contact and is electrically connected to the gate pad via a second contact; and
a second polysilicon comprising at least a second trench structure of the plurality of second trench structures, the second polysilicon is electrically connected to the gate runner via a first contact and is not electrically connected to the gate pad via a second contact.

20. The semiconductor device according to claim 15, wherein
each of at least two of the second trench structures comprises:
a first contact that is electrically connected to a gate runner; and
a second contact that is separated from the first contact and electrically connected to a gate pad, and
the plurality of the second trench structures comprises:
a first polysilicon comprising at least a second trench structure of the plurality of second trench structures, the first polysilicon is electrically connected to a gate runner via a first contact and is electrically connected to a gate pad via a second contact; and
a second polysilicon comprising at least a second trench structure of the plurality of second trench structures, the second polysilicon is not electrically connected to the gate runner via a first contact and is electrically connected to the gate pad via a second contact.
